(19) United States
(12) Patent Application Publication
(10) Pub. No.: US 2021/0408131 A1
(43) Pub. Date: Dec. 30, 2021

(54) ORGANIC LIGHT EMITTING DIODE DISPLAY PANEL AND MANUFACTURING METHOD THEREOF

(71) Applicant: Wuhan China Star Optoelectronics Semiconductor Display Technology Co., LTD., Wuhan, Hubei (CN)

(72) Inventors: Xiaowen HUANG, Wuhan (CN); Lei WANG, Wuhan (CN); Wenliang GONG, Wuhan (CN); Wenxu XIANYU, Wuhan (CN)

(73) Assignee: Wuhan China Star Optoelectronics Semiconductor Display Technology Co., LTD., Wuhan, Hubei (CN)

(21) Appl. No.: 16/631,883

(22) PCT Filed: Oct. 11, 2019
(86) PCT No.: PCT/CN2019/110550

§ 371 Date: Jan. 17, 2020

(30) Foreign Application Priority Data
Sep. 6, 2019 (CN) 201910840165.2

(51) Int. Cl. H01L 27/32; H01L 51/52; H01L 51/56

(52) U.S. Cl. CPC H01L 27/322; H01L 27/3246; H01L 27/3272; H01L 51/56; H01L 51/5237; H01L 51/5284; H01L 27/3262

(57) ABSTRACT

The present invention provides an organic light emitting diode (OLED) display panel and a manufacturing method thereof. The OLED display panel includes a base substrate, a thin film transistor array layer, a pixel definition layer, an organic light emitting layer, an encapsulation layer and a color filter layer. The color filter layer includes a first color filter layer, a second color filter layer, and a third color filter layer that are stacked sequentially to form a light shielding portion for replacing the black matrix, which lowers a risk of reduction of light emitting efficiency of the OLED device or failure of the OLED device and enhances optical effect and folding capability of the OLED display panel.

### FIELD OF INVENTION

The present invention relates to a field of display technologies, especially to an organic light emitting diode (OLED) display panel and a manufacturing method thereof.

### BACKGROUND OF INVENTION

Adding a polarizer (POL) into a display panel can effectively reduce a reflectivity of the display panel under glare but it also as defects as follows. In one aspect, the polarizer reduces about 58% of outputting light, especially to an organic light emitting diode (OLED) display panel, a lifespan thereof is extremely reduced. In another aspect, the polarizer with a great thickness and brittle material advantages development of dynamic folding products. To develop dynamic folding products based on OLED display technologies, it is necessary to import new material, new technologies, and new processes for replacing the polarizer.

A technology using a color filter layer for replacing a polarizer belongs to a polarizer-less (POL-less) technology and has a color filter layer composited of red color resists, green color resists, blue color resists, and a black matrix (BM). The black matrix mainly functions to prevent light leakage of display panel and reduce reflection of the display panel. The red color resists, the green color resists, and the blue color resists are responsive respectively for outputting light for red sub-pixels, green sub-pixels, and blue sub-pixels, and simultaneously prevent reflection of anodes of the OLED display panel. However, manufacture of the black matrix, the red color resists, the green color resists, and the blue color resists requires at least lithography processes of four masks such that the manufacturing process thereof is complicated. Furthermore, multiple wet etching processes and baking processes increases pressure on an encapsulation layer repelling water oxygen, which increases a risk of reduction of light emitting efficiency of the OLED device or failure of the OLED device.

As described above, it is necessary to provide a new OLED display panel and a manufacturing method thereof to solve the above technical issues.

### SUMMARY OF INVENTION

### Technical Issue

An organic light emitting diode (OLED) display panel and a manufacturing method thereof provided by the present invention solve the technical issue that a conventional OLED display panel employing polarizer-less (POL-less) has complicated manufacturing processes and multiple wet etching processes and baking processes thereof increase pressure on an encapsulation layer repelling water oxygen, which increases a risk of reduction of light emitting efficiency of the OLED device or failure of the OLED device.

### Technical Solution

To solve the above issue, the present invention provides technical solutions as follows.

An embodiment of the present invention provides an organic light emitting diode (OLED) display panel, comprising:
a base substrate;
a thin film transistor array layer disposed on the base substrate;
a pixel definition layer disposed on the thin film transistor array layer, and the pixel definition layer comprising a plurality of light emitting regions and a plurality of non-light emitting regions located among the light emitting regions;
an organic light emitting layer disposed in the light emitting regions, wherein the organic light emitting layer comprises a plurality of first light emitting units, second light emitting units, and third light emitting units distributed at intervals;
an encapsulation layer covering the pixel definition layer and the organic light emitting layer; and
a color filter layer disposed on the encapsulation layer, and the color filter layer comprising a first color filter layer, a second color filter layer, and a third color filter layer, wherein the first color filter layer corresponds to the first light emitting units and the non-light emitting regions, the second color filter layer corresponds to the second light emitting units and the non-light emitting regions, the third color filter layer corresponds to the third light emitting units and the non-light emitting regions, and on the encapsulation layer corresponding to the non-light emitting regions, the first color filter layer, the second color filter layer, and the third color filter layer are sequentially stacked to form a light shielding portion, and an optical density of the light shielding portion is greater than 3.

According to an OLED display panel provided by an embodiment of the present invention, material of the pixel definition layer is black light shielding material.

According to an OLED display panel provided by an embodiment of the present invention, material of the pixel definition layer is black resin.

According to an OLED display panel provided by an embodiment of the present invention, colors displayed by the first light emitting units, the second light emitting units and the third light emitting units are respectively the same as colors of the first color filter layer, the second color filter layer, and the third color filter layer that are disposed correspondingly.

According to an OLED display panel provided by an embodiment of the present invention, the colors of the first color filter layer, the second color filter layer, and the third color filter layer are red, green, and blue arranged randomly.

According to an OLED display panel provided by an embodiment of the present invention, a thickness of the light shielding portion in the non-light emitting regions is uniform.

According to an OLED display panel provided by an embodiment of the present invention, the OLED display panel further comprises a planarization layer, and the planarization layer is disposed on the color filter layer.

An embodiment of the present invention provides an organic light emitting diode (OLED) display panel, comprising:

a base substrate;

a thin film transistor array layer disposed on the base substrate;

a pixel definition layer disposed on the thin film transistor array layer, and the pixel definition layer comprising a plurality of light emitting regions and a plurality of non-light emitting regions located among the light emitting regions;

an organic light emitting layer disposed in the light emitting regions, wherein the organic light emitting layer comprises a plurality of first light emitting units, second light emitting units, and third light emitting units distributed at intervals;

an encapsulation layer covering the pixel definition layer and the organic light emitting layer; and

a color filter layer disposed on the encapsulation layer, and the color filter layer comprising a first color filter layer, a second color filter layer, and a third color filter layer, wherein the first color filter layer corresponds to the first light emitting units and the non-light emitting regions, the second color filter layer corresponds to the second light emitting units and the non-light emitting regions, the third color filter layer corresponds to the third light emitting units and the non-light emitting regions, and on the encapsulation layer corresponding to the non-light emitting regions, the first color filter layer, the second color filter layer, and the third color filter layer are sequentially stacked to form a light shielding portion.

According to an OLED display panel provided by an embodiment of the present invention, material of the pixel definition layer is black light shielding material.

According to an OLED display panel provided by an embodiment of the present invention, material of the pixel definition layer is black resin.

According to an OLED display panel provided by an embodiment of the present invention, colors displayed by the first light emitting units, the second light emitting units and the third light emitting units are respectively the same as colors of the first color filter layer, the second color filter layer, and the third color filter layer that are disposed correspondingly.

According to an OLED display panel provided by an embodiment of the present invention, the first color filter layer, the colors of the first color filter layer, the second color filter layer, and the third color filter layer are red, green, and blue arranged randomly.

According to an OLED display panel provided by an embodiment of the present invention, a thickness of the light shielding portion in the non-light emitting regions is uniform.

According to an OLED display panel provided by an embodiment of the present invention, the OLED display panel further comprises a planarization layer, and the planarization layer is disposed on the color filter layer.

An embodiment of the present invention provides an OLED display panel manufacturing method, comprising:

a step S10: sequentially forming a thin film transistor array layer and a pixel definition layer on a base substrate, wherein the pixel definition layer comprises a plurality of light emitting regions and a plurality of non-light emitting regions located among the light emitting regions;

a step S20: forming an organic light emitting layer in the light emitting regions, wherein the organic light emitting layer comprises a plurality of first light emitting units, second light emitting units, and third light emitting units distributed at intervals;

a step S30: forming an encapsulation layer on the pixel definition layer and the organic light emitting layer;

a step S40: coating a first color resist layer on the encapsulation layer, and exposing and developing the first color resist layer by a first mask to form a first color filter layer corresponding to the first light emitting units and the non-light emitting regions;

a step S50: coating a second color resist layer on the encapsulation layer and the first color filter layer, and exposing and developing the second color resist layer by a second mask to form a second color filter layer corresponding to the second light emitting units and the non-light emitting regions; and

a step S60: coating a third color resist layer on the encapsulation layer and the second color filter layer, and exposing and developing the third color resist layer to form a third color filter layer corresponding to the third light emitting units and the non-light emitting regions, wherein in the non-light emitting regions, the first color filter layer, the second color filter layer, and the third color filter layer are stacked on one another to form a light shielding portion.

According to the OLED display panel manufacturing method provided by an embodiment of the present invention, the pixel definition layer is made of black light shielding material.

According to the OLED display panel manufacturing method provided by an embodiment of the present invention, colors displayed by the first light emitting units, the second light emitting units and the third light emitting units are respectively the same as colors of the first color filter layer, the second color filter layer, and the third color filter layer that are disposed correspondingly.

According to the OLED display panel manufacturing method provided by an embodiment of the present invention, the colors of the first color filter layer, the second color filter layer, and the third color filter layer are red, green, and blue arranged randomly.

According to the OLED display panel manufacturing method provided by an embodiment of the present invention, a hole is defined respectively in each of the first mask, the second mask, and the third mask and is configured to form each of the first color filter layer, the second color filter layer, and the third color filter layer.

According to the OLED display panel manufacturing method provided by an embodiment of the present invention, the encapsulation layer is encapsulated by a thin film.

### Advantages

Advantages of the present invention are as follows. The OLED display panel and the manufacturing method thereof provided by the present invention, by stacking the red color resists, green color resists, and blue color resists on the encapsulation layer of the corresponding non-light emitting regions to form a light shielding portion for replacing a black matrix, optimize the processes, reduce a manufacturing period, extremely lower costs of production apparatuses, masks, and material, and reduce the risk of lowered light emitting efficiency of the OLED device or failure of the OLED device after a lithography process. Furthermore, the pixel definition layer thereof also has a light shielding effect and can combine the light shielding portion to further enhance an optical effect and a folding capability of the OLED display panel.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic view of an organic light emitting diode (OLED) display panel provided by a first embodiment of the present invention;

FIG. 2 is a flowchart of an OLED display panel manufacturing method provided by a second embodiment of the present invention;

FIG. 3 is a schematic view of a step S10 of an OLED display panel manufacturing method provided by the second embodiment of the present invention;

FIG. 4 is a schematic view of a step S20 of an OLED display panel manufacturing method provided by the second embodiment of the present invention;

FIG. 5 is a schematic view of a step S30 of an OLED display panel manufacturing method provided by the second embodiment of the present invention;

FIG. 6 is a schematic view of a step S40 of an OLED display panel manufacturing method provided by the second embodiment of the present invention;

FIG. 7 is a schematic view of a step S50 of an OLED display panel manufacturing method provided by the second embodiment of the present invention; and

FIG. 8 is a schematic view of step S60 of an OLED display panel manufacturing method provided by the second embodiment of the present invention.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.
the present invention aims at the issue that a conventional organic light emitting diode (OLED) display panel and a manufacturing method thereof have complicated manufacturing processes and multiple wet etching processes and baking processes thereof increase pressure on an encapsulation layer repelling water oxygen, which increases a risk of reduction of light emitting efficiency of the OLED device or failure of the OLED device. The present embodiment can solve the defect.

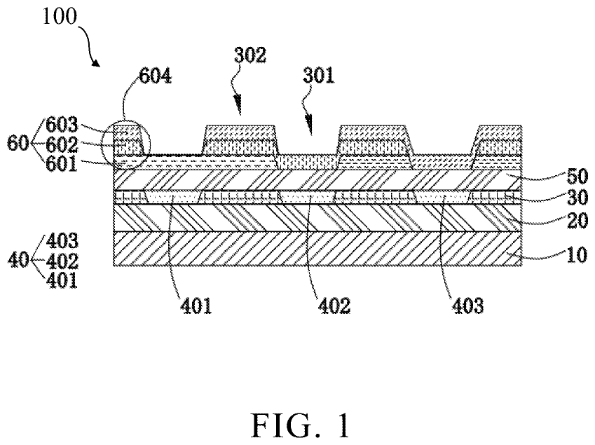

With reference to FIG. 1, an OLED display panel 100 provided by an embodiment of the present invention comprises a base substrate 10, a thin film transistor array layer 20, a pixel definition layer 30, an organic light emitting layer 40, an encapsulation layer 50, and a color filter layer 60 that are disposed sequentially.

The base substrate 10 is a flexible substrate optionally employing polyimide (PI) material.

The thin film transistor array layer 20 is disposed on the base substrate 10 and is formed with a pixel drive circuit of the OLED display panel 100.

The pixel definition layer 30 is disposed on the thin film transistor array layer 20, and the pixel definition layer 30 comprises a plurality of light emitting regions 301 and non-light emitting regions 302 located among the light emitting regions 301.

The organic light emitting layer 40 is disposed in the light emitting regions 301, and the organic light emitting layer 40 comprises a plurality of first light emitting units 401, second light emitting units 402, and third light emitting units 403 distributed at intervals. Displayed colors of the first light emitting units 401, the second light emitting units 402, and the third light emitting units 403 are different.

The encapsulation layer 50 covers the pixel definition layer 30 and the organic light emitting layer 40, and is configured to prevent internal structures of the OLED device from corrosion of water oxygen to enhance a lifespan thereof.

The color filter layer 60 is disposed on the encapsulation layer 50, and the color filter layer 60 comprises a first color filter layer 601, a second color filter layer 602, and a third color filter layer 603. The first color filter layer 601 corresponds to the first light emitting units 401 and the non-light emitting regions 302. The second color filter layer 602 corresponds to the second light emitting units 402 and the non-light emitting regions 302. The third color filter layer 603 corresponds to the third light emitting units 403 and the non-light emitting regions 302. Furthermore, in correspondence with the encapsulation layer 50 of the non-light emitting regions 302, the first color filter layer 601, the second color filter layer 602, and the third color filter layer 603 are sequentially stacked to form a light shielding portion 604.

To guarantee a minimized loss of light and enhancement of display brightness, displayed colors of the first light emitting units 401, the second light emitting units 402, and the third light emitting units 403 are the same as colors of the first color filter layer 601, the second color filter layer 602, and the third color filter layer 603 corresponding thereto. Furthermore, the first light emitting units 401, the second light emitting units 402, and the third light emitting units 403 are aligned with the first color filter layer 601, the second color filter layer 602, and the third color filter layer 603, for example, the light emitting units displaying red are aligned with the red color filter layer on the color filter layer 60.

Specifically, the colors of the first color filter layer 601, the second color filter layer 602, and the third color filter layer 603 are red, green, and blue arranged randomly. Theoretically six arrangements exist, and specific arrangements are red green blue, red blue green, green red blue, green blue red, blue red green, blue green red. In an embodiment of the present invention, the color of the first color filter layer 601 is red, the color of the second color filter layer 602 is green, and the color of the third color filter layer 603 is blue.

The light shielding portion 604 is disposed between adjacent two of the light emitting units. One of the color filter layers of the light shielding portion 604 is connected to the color filter layer on an adjacent one of the light emitting regions 301 and both has the same color, and the light shielding portion 604 corresponds to the non-light emitting regions 302. In an embodiment of the present invention, the light shielding portion 604 comprises a red light filter layer, a green light filter layer, and a blue light filter layer arranged from bottom to top. According to a principle of color subtraction of three primary colors, when a backlight of the OLED display panel 100 emits white light, the first color filter layer 601, the second color filter layer 602, and the third color filter layer 603 in the light shielding portion 604 selectively absorb lights of different wavelengths. In other words, the first color filter layer 601 absorbs red light, the second color filter layer 602 absorbs green light, and the third color filter layer 603 absorbs blue light, and an accumulated effect is that the light shielding portion 604 completely absorbs the incident white light such that the non-light emitting regions displays black to achieve the same effect as performed by a black matrix to effectively prevent light leakage and reflection of the OLED display panel.

A thickness of the light shielding portion 604 affects a light shielding effect thereof. In general, only when an optical density (OD) of the light shielding portion 604 is greater than 3, can the accumulated effect of the light shielding portion 604 display black, as performed by a black matrix. Therefore, an OD value of the light shielding portion 604 can be controlled by adjusting a thickness of the light shielding portion 604 to enhance a light shielding effect thereof.

A person of ordinary skill in the art can conclude from several experiments that when a thickness of the light shielding portion 604 is 6 um, an OD value of the light shielding portion 604 is still less than 3. Therefore, to achieve the same effect of a black matrix, the light shielding portion 604 needs to control the thickness of the light shielding portion 604 to be greater than 6 um. However, such thickness of the light shielding portion 604 is excessive thick, in one aspect to influence a light outputting rate of the OLED display panel 100, and in another aspect to to thicken a screen of the OLED display panel 100 to affect a folding capability thereof.

To overcome the above defects, an embodiment of the present invention employs black light shielding material as material of the pixel definition layer 30, for example black resin, to shield or absorb light without lowering the light outputting rate. Furthermore, a combination of the pixel definition layer 30 employing the black light shielding material and the light shielding portion 604 not only guarantees the OD value of the non-light emitting regions 302 being greater than 3 to further improve an optical effect of the OLED display panel 100, but also reduces the thickness of the light shielding portion 604 to further enhance the of the folding capability OLED display panel 100, which facilitates achievement of OLED dynamic folding products.

Furthermore, the OLED display panel 100 can further comprise a planarization layer, and the planarization layer is disposed on the color filter layer 60. To make the color filter layer 60 to achieve thereof, a thickness of the light shielding portion 604 is kept uniform in the non-light emitting regions 302.

### Second Embodiment

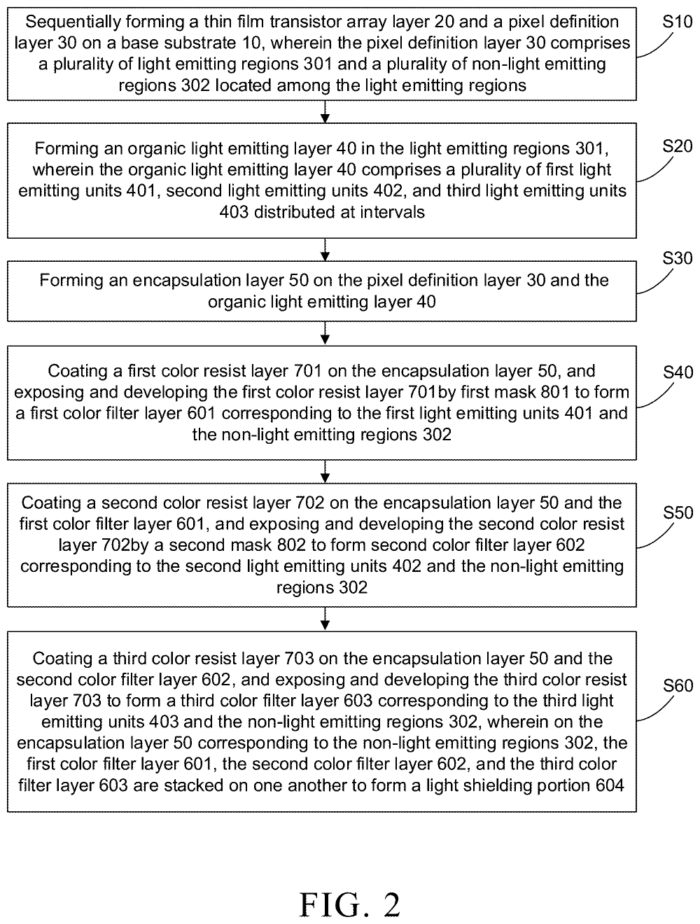

With reference to FIG. 2, it should be explained first that an embodiment of the present invention set the colors of the first color filter layer 601, the second color filter layer 602, and the third color filter layer 603 to be red, green, and blue as an example for explanation, but an embodiment of the present invention is not limited thereto. a manufacturing method for the OLED display panel 100 comprises steps provided by an embodiment of the present invention is as follows.

A step S10 comprises sequentially forming a thin film transistor array layer 20 and a pixel definition layer 30 on a base substrate 10, wherein the pixel definition layer 30 comprises a plurality of light emitting regions 301 and a plurality of non-light emitting regions 302 located among the light emitting regions.

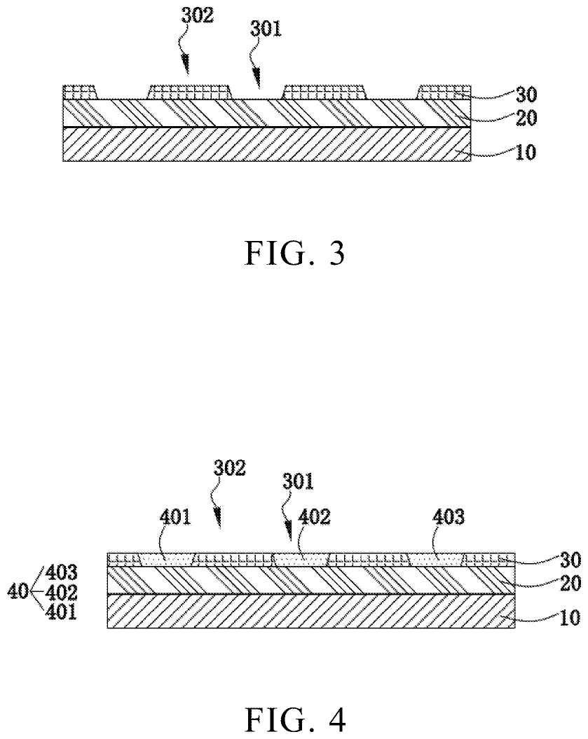

Specifically, with reference to FIG. 3, the base substrate 10 is provided, and material of the base substrate 10 comprises polyimide (PI). the thin film transistor array layer 20 is formed on the base substrate 10. The pixel definition layer 30 is formed on the thin film transistor array layer 20, and the pixel definition layer 30 comprises a plurality of light emitting regions 301 and a plurality of non-light emitting regions 302 located among the light emitting regions 301.

A step S20 comprises forming an organic light emitting layer 40 in the light emitting regions 301, wherein the organic light emitting layer 40 comprises a plurality of first light emitting units 401, second light emitting units 402, and third light emitting units 403 distributed at intervals.

Specifically, with reference to FIG. 4, the light emitting regions 301 is filled with three kinds of organic light emitting material with different light colors to form a plurality of first light emitting units 401, second light emitting units 402, and third light emitting units 403 that are distributed at intervals. In an embodiment of the present invention, a displayed color of the first light emitting units 401 is red, a displayed color of the second light emitting units 402 is green, and a displayed color of the third light emitting units 403 is blue.

A step S30 comprises forming an encapsulation layer 50 on the pixel definition layer 30 and the organic light emitting layer 40.

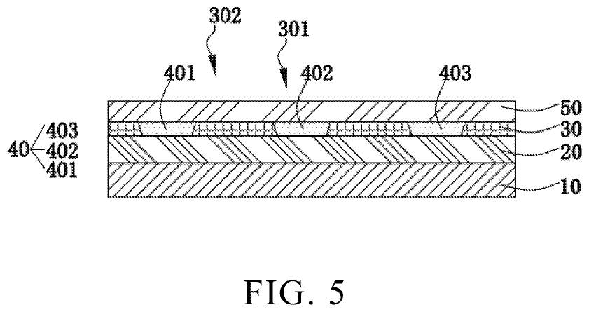

With reference to FIG. 5, the encapsulation layer 50 is a thin film encapsulation and is configured to prevent internal structures of the OLED device from corrosion of water oxygen to improve a lifespan thereof.

A step S40 comprises coating a first color resist layer 701 on the encapsulation layer 50, and exposing and developing the first color resist layer 701 by first mask 801 to form a first color filter layer 601 corresponding to the first light emitting units 401 and the non-light emitting regions 302.

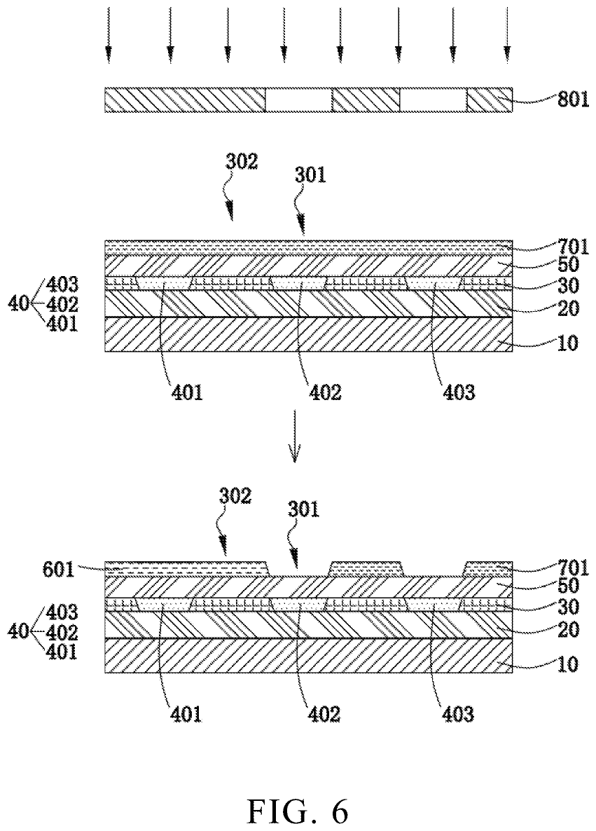

With reference to FIG. 6, the coated first color resist layer 701 is a red color resist layer, after undergoing a pre-baking process, the first color resist layer 701 is exposed and developed by the first mask 801 and is baked to cure and the retain first color resist layer 701. A hole is defined in the first mask 801 for forming the first color filter layer 601. Specifically, holes are defined respectively in regions of the first mask 801 and corresponding to the second light emitting units 402 (a displayed color thereof is green) and the third light emitting units 403 (a displayed color thereof is blue). Therefore, the first color filter layer 601 is formed and covers the first light emitting units 401 (a displayed color thereof is red) and the non-light emitting regions 302.

A step S50 comprises coating a second color resist layer 702 on the encapsulation layer 50 and the first color filter layer 601, and exposing and developing the second color resist layer 702 by a second mask 802 to form second color filter layer 602 corresponding to the second light emitting units 402 and the non-light emitting regions 302.

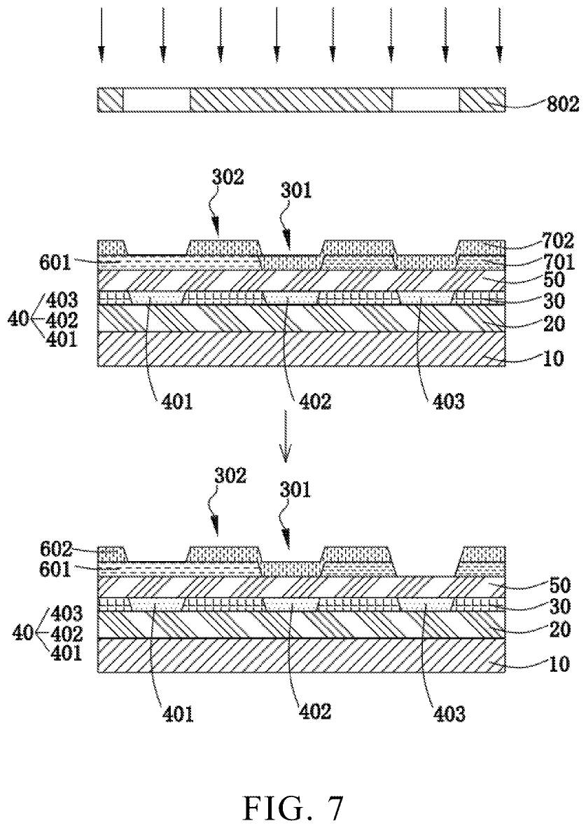

With reference to FIG. 7, the coated second color resist layer 702 is a green color resist layer. After undergoing a pre-baking process the second color resist layer 702 is exposed and developed by the first mask 801 and is baked to cure the retained second color resist layer 702. A hole is defined in the second mask 802 for forming the second color filter layer 602. Specifically, holes are defined in regions of the second mask 802 corresponding to the first light emitting units 401 (a displayed color thereof is red) and the third light emitting units 403 (a displayed color thereof is blue) such that the second color filter layer 602 is formed and covers the first light emitting units 401 (a displayed color thereof is green) and the non-light emitting regions 302.

A step S60 comprises coating a third color resist layer 703 on the encapsulation layer 50 and the second color filter layer 602, and exposing and developing the third color resist layer 703 to form a third color filter layer 603 corresponding to the third light emitting units 403 and the non-light emitting regions 302, wherein on the encapsulation layer 50 corresponding to the non-light emitting regions 302, the first color filter layer 601, the second color filter layer 602, and the third color filter layer 603 are stacked on one another to form a light shielding portion 604.

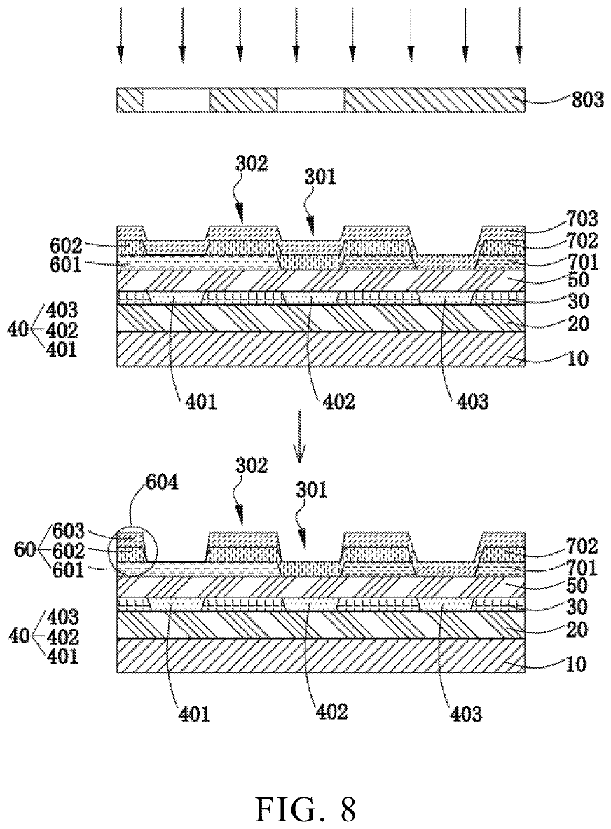

With reference to FIG. 8, the coated third color resist layer 703 is a blue color resist layer. After undergoing a pre-baking process, the third color resist layer 703 is exposed and developed by the third mask 803 and is baked to cured the retained third color resist layer 703. A hole is defined in the third mask 803 for forming the third color filter layer 603. Specifically, holes are defined regions of the third mask 803 corresponding to the first light emitting units 401 (a displayed color thereof is red) and second light emitting units 402 (a displayed color thereof is green) such that the third color filter layer 603 is formed and covers the third light emitting units 403 (a displayed color thereof is green) and the non-light emitting regions 302.

To guarantee a minimized loss of light and enhancement of display brightness, displayed colors of the first light emitting units 401, the second light emitting units 402, and the third light emitting units 403 are the same as colors of the first color filter layer 601, the second color filter layer 602, and the third color filter layer 603 corresponding thereto. Furthermore, the first light emitting units 401, the second light emitting units 402, and the third light emitting units 403 are aligned with the first color filter layer 601, the second color filter layer 602, and the third color filter layer 603, for example, the light emitting units displaying red are aligned with the red color filter layer on the color filter layer 60.

Colors of the first color filter layer 601, the second color filter layer 602, and the third color filter layer 603 are red, green, and blue arranged randomly. Therefore, theoretically six different arrangements exist and all of the arrangements can be applied to manufacture the light shielding portion, an embodiment of the present invention should not be limited thereto.

In an embodiment of the present invention, the light shielding portion 604 comprises a red light filter layer, a green light filter layer, and a blue light filter layer arranged from bottom to top. According to a principle of color subtraction of three primary colors, when a backlight of the OLED display panel 100 emits white light, the first color filter layer 601, the second color filter layer 602, and the third color filter layer 603 in the light shielding portion 604 selectively absorb lights of different wavelengths. In other words, the first color filter layer 601 absorbs red light, the second color filter layer 602 absorbs green light, and the third color filter layer 603 absorbs blue light, and an accumulated effect is that the light shielding portion 604 completely absorbs the incident white light such that the non-light emitting regions displays black to achieve the same effect as performed by a black matrix to effectively prevent light leakage and reflection of the OLED display panel 100.

An aperture size of one of light emitting units is decided by corresponding to a minimal aperture size of two color filter layers of another two of the light emitting units. Specifically, an aperture size of the first light emitting units 401 is decided by a minimal aperture size of the second color filter layer 602 and the third color filter layer 603. An aperture size of the second light emitting units 402 is decided by a minimal aperture size of the first color filter layer 601 and the third color filter layer 603. An aperture size of the third light emitting units 403 is decided by a minimal aperture size of the first color filter layer 601 and the second color filter layer 602. Preferably, the aperture size of one of the light emitting units is equal to the aperture size of anyone of color filter layer.

A thickness of the light shielding portion 604 can be achieved by adjusting a thickness of the coated first color resist layer 701, the coated second color resist layer 702, or the coated third color resist layer 703 to adjust the OD value the light shielding portion 604 to fulfill requirements.

Furthermore, material of the pixel definition layer 30 comprises black light shielding material, for example, black resin material, to be able to shield absorb light without lowering a light outputting rate. Furthermore, a combination of the pixel definition layer 30 and employing the black light shielding material and the light shielding portion 604, not only guarantees the OD value of the non-light emitting regions 302 to be greater than 3, but also further enhances an optical effect of the OLED display panel 100 to reduce the thickness of the light shielding portion 604 and to further improve the folding capability the OLED display panel 100, which facilitates achievement of the OLED dynamic folding products.

Furthermore, the manufacturing method for the OLED display panel 100 further comprises: forming a planarization layer on the color filter layer 60. To make the color filter layer 60 achieve the required planarization better, a thickness of the light shielding portion 604 in the non-light emitting regions 302 is kept uniform. In an embodiment of the present invention, by respectively controlling thicknesses of the first color filter layer 601, the second color filter layer 602, the third color filter layer 603 in the non-light emitting regions 302 to be uniform, keeping uniformity of the thickness of the light shielding portion 604 in the non-light emitting regions 302 can be achieved. Such requirement can save material of the planarization layer and lower the cost thereof.

Because the OLED display panel manufacturing method provided by an embodiment of the present invention merely requires three lithography processes to form the color filter layer 60, which is one lithography process less than a black matrix forming process in a conventional polarizer-less (POL-less) technology, which simplified manufacturing processes. Therefore, a pressure of wet etching and baking processes on the encapsulation layer repelling water oxygen can be reduced such that a risk of reduction of light emitting efficiency of the OLED device or failure of the OLED device is lowered.

Advantages are as follows. The OLED display panel and the manufacturing method thereof provided by an embodiment of the present invention, by stacking the red color resists, green color resists, and blue color resists on the encapsulation layer of the corresponding non-light emitting regions to form a light shielding portion for replacing a black matrix, optimize the processes, reduce a manufacturing period, extremely lower costs of production apparatuses, masks, and material, and reduce the risk of lowered light emitting efficiency of the OLED device or failure of the OLED device after a lithography process. Furthermore, the pixel definition layer thereof also has a light shielding effect and can combine the light shielding portion to further enhance an optical effect and a folding capability of the OLED display panel.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. An organic light emitting diode (OLED) display panel, comprising:
a base substrate;
a thin film transistor array layer disposed on the base substrate;
a pixel definition layer disposed on the thin film transistor array layer, and the pixel definition layer comprising a plurality of light emitting regions and a plurality of non-light emitting regions located among the light emitting regions;
an organic light emitting layer disposed in the light emitting regions, wherein the organic light emitting layer comprises a plurality of first light emitting units, second light emitting units, and third light emitting units distributed at intervals;
an encapsulation layer covering the pixel definition layer and the organic light emitting layer; and
a color filter layer disposed on the encapsulation layer, and the color filter layer comprising a first color filter layer, a second color filter layer, and a third color filter layer, wherein the first color filter layer corresponds to the first light emitting units and the non-light emitting regions, the second color filter layer corresponds to the second light emitting units and the non-light emitting regions, the third color filter layer corresponds to the third light emitting units and the non-light emitting regions, and on the encapsulation layer corresponding to the non-light emitting regions, the first color filter layer, the second color filter layer, and the third color filter layer are sequentially stacked to form a light shielding portion, and an optical density of the light shielding portion is greater than 3.

2. The OLED display panel as claimed in claim 1, wherein material of the pixel definition layer is black light shielding material.

3. The OLED display panel as claimed in claim 2, wherein material of the pixel definition layer is black resin.

4. The OLED display panel as claimed in claim 1, wherein colors displayed by the first light emitting units, the second light emitting units and the third light emitting units are respectively the same as colors of the first color filter layer, the second color filter layer, and the third color filter layer that are disposed correspondingly.

5. The OLED display panel as claimed in claim 4, wherein the colors of the first color filter layer, the second color filter layer, and the third color filter layer are red, green, and blue arranged randomly.

6. The OLED display panel as claimed in claim 1, wherein a thickness of the light shielding portion in the non-light emitting regions is uniform.

7. The OLED display panel as claimed in claim 1, wherein the OLED display panel further comprises a planarization layer, and the planarization layer is disposed on the color filter layer.

8. An organic light emitting diode (OLED) display panel, comprising:
a base substrate;
a thin film transistor array layer disposed on the base substrate;
a pixel definition layer disposed on the thin film transistor array layer, and the pixel definition layer comprising a plurality of light emitting regions and a plurality of non-light emitting regions located among the light emitting regions;
an organic light emitting layer disposed in the light emitting regions, wherein the organic light emitting layer comprises a plurality of first light emitting units, second light emitting units, and third light emitting units distributed at intervals;
an encapsulation layer covering the pixel definition layer and the organic light emitting layer; and
a color filter layer disposed on the encapsulation layer, and the color filter layer comprising a first color filter layer, a second color filter layer, and a third color filter layer, wherein the first color filter layer corresponds to the first light emitting units and the non-light emitting regions, the second color filter layer corresponds to the second light emitting units and the non-light emitting regions, the third color filter layer corresponds to the third light emitting units and the non-light emitting regions, and on the encapsulation layer corresponding to the non-light emitting regions, the first color filter layer, the second color filter layer, and the third color filter layer are sequentially stacked to form a light shielding portion.

9. The OLED display panel as claimed in claim 8, wherein material of the pixel definition layer is black light shielding material.

10. The OLED display pane as claimed in claim 9, wherein material of the pixel definition layer is black resin.

11. The OLED display panel as claimed in claim 8, wherein colors displayed by the first light emitting units, the second light emitting units and the third light emitting units are respectively the same as colors of the first color filter layer, the second color filter layer, and the third color filter layer that are disposed correspondingly.

12. The OLED display panel as claimed in claim 11, wherein the colors of the first color filter layer, the second color filter layer, and the third color filter layer are red, green, and blue arranged randomly.

13. The OLED display panel as claimed in claim 8, wherein a thickness of the light shielding portion in the non-light emitting regions is uniform.

14. The OLED display panel as claimed in claim 8, wherein the OLED display panel further comprises a planarization layer, and the planarization layer is disposed on the color filter layer.

15. An organic light emitting diode (OLED) display panel manufacturing method, comprising:
a step S10: sequentially forming a thin film transistor array layer and a pixel definition layer on a base substrate, wherein the pixel definition layer comprises a plurality of light emitting regions and a plurality of non-light emitting regions located among the light emitting regions;
a step S20: forming an organic light emitting layer in the light emitting regions, wherein the organic light emitting layer comprises a plurality of first light emitting units, second light emitting units, and third light emitting units distributed at intervals;
a step S30: forming an encapsulation layer on the pixel definition layer and the organic light emitting layer;
a step S40: coating a first color resist layer on the encapsulation layer, and exposing and developing the first color resist layer by a first mask to form a first color filter layer corresponding to the first light emitting units and the non-light emitting regions;
a step S50: coating a second color resist layer on the encapsulation layer and the first color filter layer, and exposing and developing the second color resist layer by a second mask to form a second color filter layer corresponding to the second light emitting units and the non-light emitting regions; and
a step S60: coating a third color resist layer on the encapsulation layer and the second color filter layer, and exposing and developing the third color resist layer to form a third color filter layer corresponding to the third light emitting units and the non-light emitting regions, wherein in the non-light emitting regions, the first color filter layer, the second color filter layer, and the third color filter layer are stacked on one another to form a light shielding portion.

16. The OLED display panel manufacturing method as claimed in claim 15, wherein the pixel definition layer is made of black light shielding material.

17. The OLED display panel manufacturing method as claimed in claim 15, wherein colors displayed by the first light emitting units, the second light emitting units and the third light emitting units are respectively the same as colors of the first color filter layer, the second color filter layer, and the third color filter layer that are disposed correspondingly.

18. The OLED display panel manufacturing method as claimed in claim 17, wherein the colors of the first color filter layer, the second color filter layer, and the third color filter layer are red, green, and blue arranged randomly.

19. The OLED display panel manufacturing method as claimed in claim 15, wherein a hole is defined respectively in each of the first mask, the second mask, and the third mask and is configured to form each of the first color filter layer, the second color filter layer, and the third color filter layer.

20. The OLED display panel manufacturing method as claimed in claim 15, wherein the encapsulation layer is encapsulated by a thin film.
